(19) United States
(12) Patent Application Publication
(10) Pub. No.: US 2009/0072670 A1
(43) Pub. Date: Mar. 19, 2009

(54) INPUT DEVICE AND METHOD FOR REGISTERING USER INPUT ON AN ELECTRONIC DEVICE

(75) Inventors: Per-Ragnar HANSSON, Stockholm (SE); Bengt NISSAR, Stockholm (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/854,662

(22) Filed: Sep. 13, 2007

(51) Int. Cl. H01L 41/00

(52) U.S. Cl. 310/338; 310/328

(57) ABSTRACT

The invention relates to an input device comprising a first conductive layer, a second conductive layer, and a piezoelectric material layer arranged in between the first conductive layer and the second conductive layer.

### TECHNICAL FIELD

The present invention relates to an input device and method for registering input from a user. In particular, the invention relates to determine an input on an electronic device.

### BACKGROUND OF THE INVENTION

Today, there is an increase in the demand of electronic devices. Different electronic devices such as stationary devices as well portable devices find their way in to all different kinds of areas. Especially, the usage of portable devices, such as PDAs, mobile phones, MP3-players and the like, are increasing tremendously. Today, there exist numerous configurations of portable devices as well as for stationary devices, such as ticket sales machines, self service information machine, and stationary computers etc. Such devices comprise a user control interface having an output device, for example in the form of a display for presenting visual information such as letters, digits and also graphics and symbols related to the operation of the device in question. For example, such an output device can be a liquid crystal display. The user control interface normally also comprises an input device for manually inputting commands or making selections related to the operation of the device.

An input device of a user control interface can for example be constituted by a touch panel arrangement, wherein the user of the device make commands by touching a screen/panel by a finger or a pointing device, such as a stylus pen or the like. By pressing a certain area of the panel the input is registered. Another input device of a user control interface may be keys of a key pad.

According to prior art an input device, such as a touch panel, can be in the form of a resistive arrangement comprising an air gap between two conductive layers. Such an arrangement is common today in mobile telephones and similar handheld devices.

In today's market for electronic devices and terminals, there is a growing demand for increasing possibilities of attractive and flexible design.

### SUMMARY OF THE INVENTION

Embodiments of the present invention address the problem of providing an input device, suitably for electronic devices, for increasing possibilities of attractive and flexible design.

An embodiment discloses an input device for registering an input from a user, wherein the touch panel is a multi-layered structure that comprises: a first conductive layer, a second conductive layer, and a piezoelectric material layer arranged in between the first conductive layer and the second conductive layer, and configured to generate a voltage indicating an input on the input device, wherein the first conductive layer, the piezoelectric material layer and the second conductive layer are arranged to form an electrical circuit configured to be used to determine the input from the user.

The input device may further comprise a measuring arrangement configured to measure the generated voltage in order to determine the input.

An embodiment discloses an input device wherein a position is determined in a coordinate system arranged on the input device comprising an x-axis and a y-axis, and the measuring arrangement comprises two measuring devices for measuring an electrical potential difference for each axis and conductive layer to determine position on each axis.

Furthermore, the measuring arrangement may be configured to be used to determine a force of the input, said force indicates a certain input.

In an embodiment, the piezoelectric material layer has a refractive index related to the refractive index of the conductive layers in the interval of

$$0 \text{,} 9 \leq \frac{{n}_{PZ}}{{n}_{CL}} \leq 1 \text{,} 1 ;$$

wherein
n_{PZ} is the refractive index of the piezoelectric material layer, and
n_{CL} is the refractive index of the conductive layer.

In addition, the input device may comprise a plurality of symbols such as letters, digits and similar characters being arranged for facilitating input commands from a user and being disposed at a defined area forming part of a top hard coat layer facing a user during operation, wherein the top hard coat layer is arranged on the first conductive layer.

Furthermore, the input device may be a touch panel.

Additionally, the input device may be an input key.

In an embodiment, an electronic device may comprise the input device arranged on a part of the electronic device, and a processor arranged to determine the input of the user based on the generated voltage.

Furthermore, the electronic device may comprise an input device that is a touch panel arranged on an active display of the electronic device, such as a LCD-display.

An embodiment discloses a method for determining an input made by a user depressing an input device of an electronic device indicating a certain input, wherein the input device comprises a first conductive layer, a second conductive layer, and a piezoelectric material layer arranged in between the first conductive layer and the second conductive layer, comprising the steps of: converting a mechanical stress in the piezoelectric material into voltage change based on a pressure applied to the input device, determining the input in a processor of the electronic device by reading a voltage using a measuring arrangement on an electric circuit formed by the first conductive layer, the piezoelectric material layer, and the second conductive layer, said voltage corresponds to a certain input.

In an embodiment the step of determining the input further comprises the steps of: determining a position of the input in a first direction by reading the voltage change from a first voltage reader and a second voltage change from a second voltage reader, determining a position of the input in a second direction by reading the voltage change from a third voltage reader and a fourth voltage change from a fourth voltage reader, and determining the input in a processor of the portable device based on the determined positions in a first direction and a second direction, said positions correspond to a certain input.

Additionally, the step of determining the input may further comprise the step of determining the input based on the pressure applied to the input device, wherein a level of a measured voltage corresponds to a certain input.

A piezoelectric material generates a voltage upon an applied force. Therefore, in an embodiment an external voltage supply between the conductive layers is not needed.

In some embodiments of the invention a piezoelectric input device may enable dynamic input, that is, a piezoelectric input device is able to register how hard the user depresses the input device. These embodiments provide possibilities of new and better kinds of user interface solutions and functions.

In some embodiments the piezoelectric material is selected so that the refractive index thereof is matched to the refractive index of the conductive layer. These embodiments provide an input device with no or small reflections. The refractive index (or index of refraction) of a medium is a measure for how much the speed of light is reduced inside the medium. A display arranged under the input device will look clear and have a high contrast in bright sunshine.

Another positive characteristic of some embodiments of a piezoelectric input device is that optical defects such as Newton rings, caused by interactions of reflection of light between two surfaces, are eliminated or significantly reduced. A piezoelectric material provides a possibility to make an input device very thin. Hence, some embodiments of a piezoelectric input device enable the production of a thinner product compared to the resistive input devices of today.

### BRIEF DESCRIPTION OF THE DRAWINGS

The invention, together with further objectives and advantages thereof, may best be understood by reference to the following description taken in conjunction with the accompanying drawings in which:

FIG. 1 shows a portable device comprising a touch panel as an input device,

FIG. 2 shows a schematic cross section of a piezoelectric input device,

FIG. 3 shows a schematic overview of how light reflect in a piezoelectric input device,

FIG. 4 shows a schematic cross section of a piezoelectric input device being depressed,

FIG. 5 shows an electrical functionality of a piezoelectric material touch panel, and

FIG. 6 shows a flow chart of a method for registering an input operation of a user of an electronic device.

### DETAILED DESCRIPTION OF EMBODIMENTS OF THE INVENTION

Embodiments of the present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

The present invention is described below with reference to block diagrams and/or flowchart illustrations of methods, apparatus (systems) and/or computer program products according to embodiments of the invention. It is understood that several blocks of the block diagrams and/or flowchart illustrations, and combinations of blocks in the block diagrams and/or flowchart illustrations, can be implemented by computer program instructions.

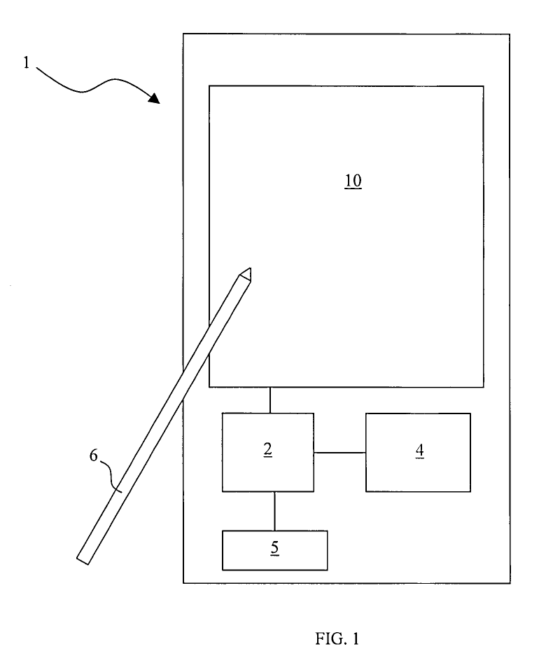

With reference to FIG. 1, there is shown a schematic overview of a portable device 1, such as a handheld, portable mobile telephone. However, the invention is not limited to such use only but can also be used in other products having user interfaces such as media players, cameras, GPS modules, palmtop computers, electronic game units, remote controls, pagers, stationary screens, stationary computers and similar devices.

The portable device 1 comprises an energy source 4, such as a battery or the like, that energize the device and its components. The portable device 1 further comprises an input device for a user of the portable device to be able to input commands and data, the input device in the illustrated embodiment is a touch panel which may be operated by using a finger, a stylus pen 6, or the like. The portable device further comprises a processor 2 or the like arranged to determine command or data from the user based on a position determined by readings of a measuring arrangement, such an arrangement may comprise a or a number of voltmeters, arranged in the portable device 1. The processor 2 is connected to a memory 5 from where the processor may get stored computer program to determine said position. The user may use a stylus pen 6, finger or the like to input data on the touch panel 10. When the data or command has been determined by the processor 2, the processor 2 performs the appropriate action to enable the electronic device to register/perform the data/command.

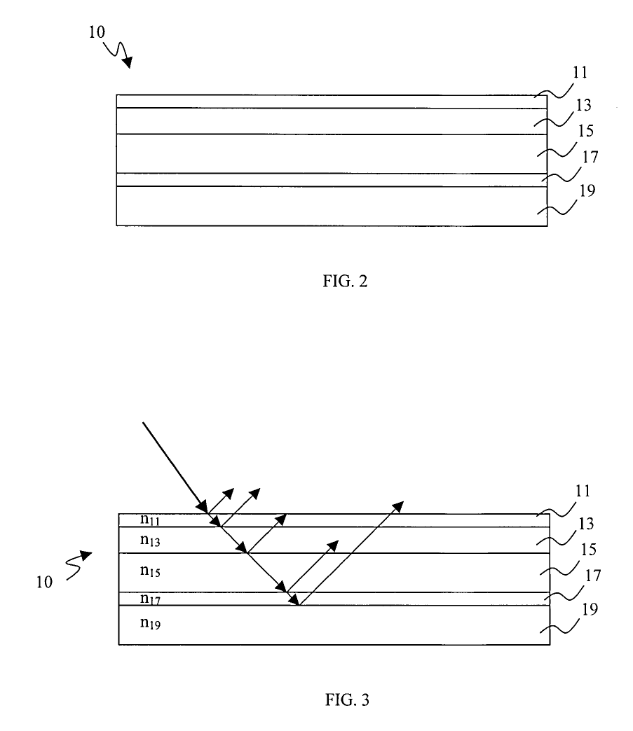

With reference to FIG. 2, a schematic and cross sectional view of an input device is shown in the form of a touch panel 10 designed in accordance with an embodiment of the invention. The touch panel 10 is suitable for use in handheld, portable mobile telephones.

An embodiment of a piezoelectric touch panel 10 is shown in FIG. 2 as a multi-layered structure. The piezoelectric touch panel may comprises a first hard coat layer 11 applied on a first conductive layer 13, wherein the hard coat layer 11 functions as a protective/isolating coating of the first conductive layer. The piezoelectric touch panel further comprises a second conductive layer 17 arranged below the first conductive layer 13 on a carrier material 19, such as glass, plastic or the like. In an embodiment is carrier 19 an active display of a device. In between the first conductive layer 13 and the second conductive layer 17 a piezoelectric material layer 15 is arranged.

A piezoelectric material is a polarized material that converts mechanical deformation of its crystals into a charge. The material may be polarized in a vertical manner or a lateral manner. The vertical polarized material generates a charge that is higher than the lateral polarized material when being compressed vertically which may be desired in order to make it easier to detect the input from a user. The charge is then converted into a voltage. A greater deformation will result in a higher charge and consequently a higher voltage. That is;

Q=p×F, wherein

Q—Resulting Charge

p=piezoelectric coefficient of the material

F=force on the material layer

And the generated voltage is;

$$V = \frac{Q}{C} ,$$

wherein

V—Voltage, and

C—Total Capacitance over the layer

It should be noted that in an embodiment a number of piezoelectric material layers are stacked in order to generate a higher voltage and a wider span of voltage.

Icons, text, symbols or the like of the user interface may be presented to the user on the hard coat layer 11, wherein the icon and the like are printed on the hard coat layer or, in an portable device wherein positions of menus or functions and the like, for example, of the touch panel, may change during use, the different icons, symbols or the like, is displayed from an active display arranged below the touch panel. An embodiment of an electronic device may also comprise a combination of an illuminating arrangement from below and printed symbols on the hard coat layer 11.

The hard coat layer 11 may be a yieldable, yet hard material such as plastic, PET or the like, in order to flex during depression and still protect the input device/electronic device from its surroundings.

The conductive layers 13, 17 may be Indium Tin Oxide (ITO) layers or layers of any other conductive material. It should here be noted in the embodiment wherein a display is arranged below the touch panel the conductive layers need to be transparent in order to be able to present the display as in the example of ITO. This in its turn requires the layers to be very thin. In an embodiment wherein the symbols or the like are displayed by means of the coat layer the conductive layers may be opaque.

The conductive layers may, for example, be vaporized into the piezoelectric material, heated and then melted onto conductive layers, etched to the piezoelectric material or arranged to each other omitting an air gap between the layers by any other known method. The different layers may also be arranged to each other by glue, adhesive or the like.

The layers may be arranged in a frame arranged on the electronic device, wherein the frame structure accommodates the touch panel. However, in another embodiment the touch panel is arranged flat onto the display, as an alternative of protective glass/plastic of displays, forming a flat design of the device.

The piezoelectric material 15 may be Lead zirconate titanate (Pb(ZrTi)O3), Strontium titanate (SrTiO3), Potassium niobate (KNbO3), Lithium niobate (LiNbO3), Lithium tantalate (LiTaO3), Bismuth ferrite (BiFeO3), Sodium tungstate (NaxWO3), Ba2NaNb5O5, Pb2KNb5O15, Quartz, Tourmaline, Topaz, cane sugar, Rochelle salt, Berlinite (AlPO4)—a quartz analogue crystal, Gallium orthophosphate (GaPO4)—a quartz analogue crystal, Langasite (La3Ga5SiO14)—a quartz analogue crystal, the family of ceramics with perovskite or tungsten-bronze structures, Barium titanate (BaTiO3), Polyvinylidene fluoride (PVDF) or the like. The material may be transparent or opaque and may approximately have a thickness of 10 μm.

Referring to FIG. 3, in an embodiment the piezoelectric material of the piezoelectric material layer 15 is selected in order to provide an input device that is clear and has a high contrast in bright sunshine with a minimum of reflections. In this embodiment the piezoelectric material is selected so that the refractive index n₁₅ of the piezoelectric material is matched to the refractive index n₁₃, n₁₇ of the conductive layers 13, 17 and hence, an input device is provided with small reflections. The refractive index (or index of refraction) of a medium is a measure for how much the speed of light is reduced inside the medium. The refractive index n of a medium is defined as the ratio of the phase velocity c of a light/sound wave phenomenon in a reference medium to the phase velocity vₚₕ in the medium itself:

$$n = \frac{c}{{v}_{p h}}$$

A display under the input device, such as a touch panel, in this embodiment will look clear and have a high contrast in bright sunshine.

The refractive index relation of the different layers may be in the interval of

$$0 \text{,} 9 \leq \frac{{n}_{15}}{{n}_{13}} \leq 1 \text{,} 1 and 0 \text{,} 9 \leq \frac{{n}_{15}}{{n}_{17}} \leq 1 \text{,} 1$$

in order to reduce the reflections. It should be noted that the material of the hard coat layer as well as the carrier may also be selected based on refractive index.

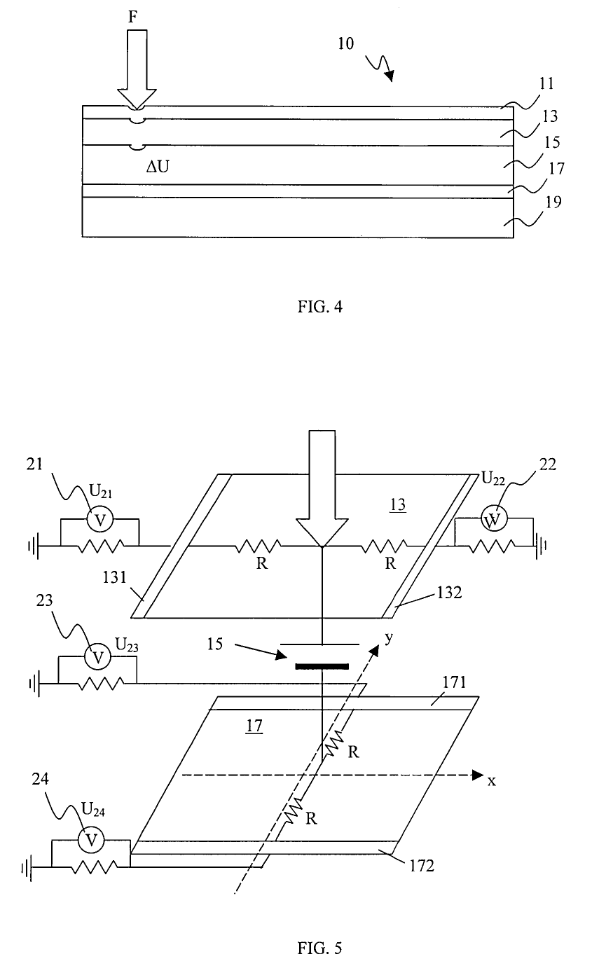

Referring to FIG. 4, when a pressure F is applied at a certain location of the input device 10 the coat layer 11 and the first conductive layer 13 is deformed so that a pressure also will be applied on the piezoelectric material layer 15. The piezoelectric layer 15 is thereby deformed so that it generates a voltage ΔU. The greater the force applied by the user, the greater the voltage generated. Hence, a piezoelectric touch panel generates its own voltage and does not need additional power sources to determine position of input. The hard coat layer 10 need to approximately deform 0.1 mm in order to get an input registered, as opposed to resistive touch panels that need a deformation of 1 mm. Hence, a piezoelectric touch panel may be more compact enabling, for example, the hard coat layer to be thicker and thereby more durable and/or the portable device to be thinner.

It should be noted that an embodiment that is very sensitive to the touch input may require a key-lock feature. The input registration of the input device may also be tuned in to different levels of input force. Other ways of operating a sensitive touch input device may be by using a double finger input, i.e. using two-finger touch during the input, and/or an initiating hard input registration followed by a soft selection input or the like.

In FIG. 5, an electrical functionality of an embodiment of a piezoelectric touch panel is shown. The piezoelectric touch panel comprises a first conductive layer 13, a second conductive layer 17 and a piezoelectric material 15 indicated as a voltage supply. The piezoelectric material layer generates a voltage ΔU when being compressed as in the case of applied pressure the touch panel. The voltage is measured by a number of measuring devices 21-24 for measuring an electrical potential difference between two points in an electric circuit, such as a voltmeter or the like. A resistance in the conductive layer is denoted as resistors R in the figure. As the resistance changes over the conductive layer the difference between a first voltmeter 21 and a second voltmeter 22 indicates a position in, for example, x direction, wherein a higher voltage reading indicates that the position is closer to that voltmeter. In a similar manner the y position is determined by comparing the readings of a third voltmeter 23 and a fourth voltmeter 24.

It should be noted that the measuring devices may be arranged inside the device and conductors, denoted as 131,132,171,172, of the conductive layers may be hidden under a coating of a graphic film applied onto the top layer or the conductive layer.

In FIG. 5 a coordinate system has been added. In order to determine the position of the input in the coordinate system a voltage relation may be used wherein

$$\frac{{U}_{22}}{{U}_{21}} > 1$$

is a position on the positive side of the x-axis,

$$\frac{{U}_{22}}{{U}_{21}} = 1$$

is a position along the centre of the coordinate system in the x direction, and

$$\frac{{U}_{22}}{{U}_{21}} < 1$$

is a position on the negative side of the x-axis. In a similar manner,

$$\frac{{U}_{24}}{{U}_{23}} > 1$$

is a position on the positive side of the y-axis,

$$\frac{{U}_{24}}{{U}_{23}} = 1$$

is a position along the centre of the coordinate system in the y direction, and

$$\frac{{U}_{24}}{{U}_{23}} < 1$$

is a position on the negative side of the y-axis.

Any other method of detecting positioning of a generated voltage may be used.

In an embodiment the first conductive layer may be connected to ground, wherein the conductive layer also protects the panel from electrostatic discharge (ESD). However, in another embodiment the second conductive layer may be connected to ground. When determining the position the measuring arrangement may first measure the voltages in one direction and, with a small delay, for example, 1 ms, measure voltages in the other direction. It should also be noted that the conductive layers may alternately be connected to ground.

It is, furthermore, possible to determine how hard the user presses down the position of the input device based on the readings. In an embodiment arranged to determine how hard a user presses down the touch panel, a first predetermined threshold value is set as a start up voltage value to detect that the touch panel is actually touched. The way of determining how hard the touch screen is pressed may be determined by setting up different threshold values above the first predetermined threshold value indicating different actions when reached. Alternatively, the determination on how hard may be based on actual continuous voltage readings. It should here be noted that the thickness of piezoelectric material may increase the span of voltage, such as adding a new layer or the like, and, hence, the possibility to differentiate different pressures to different selected actions. In an embodiment the readings of the different voltmeters in every axis is summarized in order to determine how hard the user has pressed down on the input section.

It should here be noted that even if described embodiments focus on the operation of a touch panel, the multilayer structure may also be used in a device comprising an input device comprising a number of input keys. Hence, a multilayer structure is arranged below each key and configured to generate a voltage indicating how hard the input key is depressed. This embodiment will provide the possibility of a device with an input key set, wherein each key may comprise multi functions, such as a first function when the key is depressed softly and a second function when the key is depressed hard. Furthermore, an input device comprising an input key may be arranged as a rocker button, wherein a first function is activated when the key is depressed on one side and another function is activated when depressed on the other side. A measuring arrangement is used to determine which function/side that has been selected/depressed. An embodiment may also involve a combination of determining which side and how hard the side is depressed.

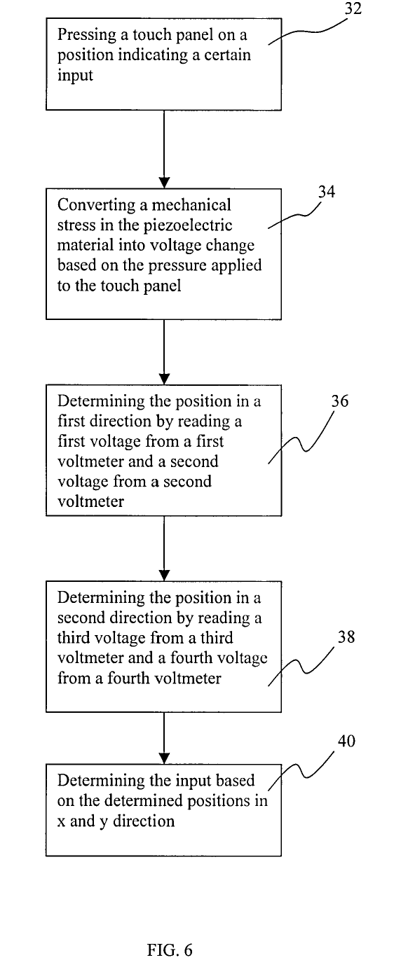

In FIG. 6, a flowchart of a method of a user making an input operation of a portable device comprising a touch panel. However, the invention is not limited to such use only but can also be used in other products having user interfaces as stated above. In the illustrated example different areas of the touch panel registers different input from the user. In other embodiments the input device may merely register how hard a user depresses the input device, or may determine a combination of pressure and position to determine selected input.

In step 32, a user of a portable device presses the touch panel on a position indicating the certain input.

In step 34, a piezoelectric electric material arranged in the touch panel receives a pressure corresponding to the pressure applied by the user on the selected position. This pressure compresses the piezoelectric material and the mechanical stress in the piezoelectric material is converted into voltage change.

In step 36, the position in a first direction is determined by reading a first voltage from a first voltmeter and a second voltage from a second voltmeter and comparing the readings in a processor arranged in the portable device.

In step 38, the position in a second direction is determined by reading a third voltage from a third voltmeter and a fourth voltage from a fourth voltmeter and comparing the readings by the processor arranged in the portable device.

In step 40, the processor determines the input of the user based on the determined positions in the two directions running a program stored in a memory of the portable device.

It should also be noted that the method may further comprise a step wherein the pressure of the input made by the user is determined by the readings of the voltmeters.

The possibility of determining how hard a position is pressed by a user increases the number of functions and applications of a portable device. Such functions may be indicating how fast a page should be scrolled down, when an icon that is activated by a soft touch a roll down selection menu may be displayed and a hard touch activates the function/program of the icon and the like. Also this may work well in a three dimensional graphical user interface whereas a selection pointer of the graphical user interface may be moving inwardly into the panel when the panel is depressed hard.

The foregoing has described the principles, preferred embodiments and modes of operation of the present invention. However, the invention should be regarded as illustrative rather than restrictive, and not as being limited to the particular embodiments discussed above. It should therefore be appreciated that variations may be made in those embodiments by those skilled in the art without departing from the scope of the present invention as defined by the following claims.

1. An input device for registering an input from a user, wherein the touch panel is a multi-layered structure that comprises:
a first conductive layer,
a second conductive layer, and
a piezoelectric material layer arranged in between the first conductive layer and the second conductive layer, and configured to generate a voltage indicating an input on the input device, wherein the first conductive layer, the piezoelectric material layer and the second conductive layer are arranged to form an electrical circuit configured to be used to determine the input from the user.

2. An input device according to claim 1, comprising a measuring arrangement configured to measure the generated voltage in order to determine the input.

3. An input device according to claim 2, wherein a position is determined in a coordinate system arranged on the input device comprising an x-axis and a y-axis, and the measuring arrangement comprises two measuring devices for measuring an electrical potential difference for each axis and conductive layer to determine position on each axis.

4. An input device according to claim 2, wherein the measuring arrangement is configured to be used to determine a force of the input, said force indicates a certain input.

5. An input device according to claim 1, wherein the piezoelectric material layer has a refractive index related to the refractive index of the conductive layers in the interval of 0,9≦n_{PZ}/n_{CL}≦1,1; wherein
n_{PZ} is the refractive index of the piezoelectric material layer, and
n_{CL} is the refractive index of the conductive layer.

6. An input device according to claim 1, comprising a plurality of symbols such as letters, digits and similar characters being arranged for facilitating input commands from a user and being disposed at a defined area forming part of a top hard coat layer facing a user during operation, wherein the hard coat layer is arranged on the first conductive layer.

7. An input device according to claim 1, wherein the input device is a touch panel.

8. An input device according to claim 1, wherein the input device is an input key.

9. An electronic device comprising an input device according to claim 1 arranged on a part of the electronic device, and a processor arranged to determine the input of the user based on the generated voltage.

10. An electronic device according to claim 9, wherein the input device is a touch panel arranged on an active display of the electronic device, such as a LCD-display.

11. A method for determining an input made by a user depressing an input device of an electronic device indicating a certain input, wherein the input device comprises a first conductive layer, a second conductive layer, and a piezoelectric material layer arranged in between the first conductive layer and the second conductive layer, comprising the steps of:
converting a mechanical stress in the piezoelectric material into voltage change based on a pressure applied to the input device,
determining the input in a processor of the electronic device by reading a voltage using a measuring arrangement on an electric circuit formed by the first conductive layer, the piezoelectric material layer, and the second conductive layer, said voltage corresponds to a certain input.

12. A method according to claim 11, wherein the step of determining the input further comprises the steps of:
determining a position of the input in a first direction by reading the voltage change from a first voltage reader and a second voltage change from a second voltage reader,
determining a position of the input in a second direction by reading the voltage change from a third voltage reader and a fourth voltage change from a fourth voltage reader, and
determining the input in a processor of the portable device based on the determined positions in the first direction and the second direction, said positions correspond to a certain input.

13. A method according to claim 11, wherein the step of determining the input further comprises the step of:
determining the input based on the pressure applied to the input device, wherein a level of a measured voltage corresponds to a certain input.
